(19) United States
(12) Patent Application Publication
(10) Pub. No.: US 2017/0135257 A1
(43) Pub. Date: May 11, 2017

(54) APPARATUS, METHODS, AND SYSTEMS FOR REMOVING COMPONENTS FROM A CIRCUIT BOARD

(71) Applicant: EMPIRE TECHNOLOGY DEVELOPMENT LLC, Wilmington, DE (US)

(72) Inventor: Wusheng Wang, Shanghai (CN)

(21) Appl. No.: 15/318,650

(22) PCT Filed: Jun. 18, 2014
(86) PCT No.: PCT/CN2014/080192

§ 371 Date: Dec. 13, 2016

(51) Int. Cl. H05K 13/04; B09B 3/00; B23K 3/02; H01L 23/00; B23K 1/018; B23K 1/00

(52) U.S. Cl. CPC H05K 13/0486; B23K 1/018; B23K 1/0016; B23K 3/029; H01L 24/98; B09B 3/00; B23K 2201/42

(57) ABSTRACT

A detachment apparatus for detaching at least one component (120) from a circuit board (125) can include a shaft (105) configured to rotate about a central axis, at least one lever (110) having a first end and a second end, the lever being attached to the shaft at the first end, and a hook (115) attached to the second end of the lever. Rotation of the shaft causes the hook to come into contact with the component on the circuit board, and the hook is configured to separate the component from the circuit board.

### BACKGROUND

As more electronic products are being consumed and then abandoned, an increasing number of waste circuit boards are produced. To recycle the waste circuit boards, the components on the boards may first be detached from the boards. Currently, there are several methods for disassembling and detaching components from a waste circuit board, including: air heating, infrared heating, laser heating, and liquid heating. However, there remains a need to effectively detach components connected to circuit boards with through-hole technology (THT).

### SUMMARY

The foregoing summary is illustrative only and is not intended to be in any way limiting. In addition to the illustrative aspects, embodiments, and features described above, further aspects, embodiments, and features will become apparent by reference to the drawings and the following detailed description.

According to some embodiments of the present disclosure, a detachment apparatus for detaching at least one component from a circuit board includes a shaft, at least one lever, and a hook attached to the lever. In some embodiments, the shaft is configured to rotate about a central axis. In some embodiments, the at least one lever has a first end and a second end, the lever being attached to the shaft at the first end. And in some embodiments, the hook is attached to the second end of the lever. In some embodiments, the rotation of the shaft causes the hook to come into contact with the at least one component. In some embodiments, the hook is configured to separate the at least one component from the circuit board.

According to some embodiments disclosed herein, a method for removing at least one component from a circuit board includes providing a circuit board having at least one component attached thereto, providing a detachment apparatus, positioning the detachment apparatus relative to the circuit board, and rotating the detachment apparatus. In some embodiments, the detachment apparatus includes a shaft configured to rotate about a central axis, at least one lever having a first end and a second end, the lever being attached to the shaft at the first end, and a hook attached to the second end of the lever. In some embodiments, rotating the detachment apparatus causes the hook to come into contact with the at least one component on the circuit board and separate the at least one component from the circuit board.

According to some embodiments of the present disclosure, a method of making a detachment apparatus includes providing a shaft configured to rotate about a central axis, attaching to the shaft at least one lever. In some embodiments, the lever has a first end and a second end, the lever being attached to the shaft at the first end, and the lever having a hook attached to the second end. In some embodiments, the hook is configured to remove at least one component from a circuit board when the shaft is rotated about the central axis.

According to some embodiments of the present disclosure, a system for detaching at least one component from a circuit board includes a detachment apparatus, a circuit board support configured to hold the circuit board in place as the hook separates the at least one component from the circuit board, and a controller configured to control, via the device, the rotation of the shaft. In some embodiments, the detachment apparatus includes a shaft configured to rotate about a central axis, at least one lever having a first end and a second end—the lever being attached to the shaft at the first end—a hook attached at the second end of the lever—the hook being configured to separate the at least one component from the circuit board, and a device configured to rotate the shaft.

These and other features will be described in greater detail below.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are not to be considered limiting of its scope, the disclosure will be described with additional specificity and detail through use of the accompanying drawings.

FIG. 1 illustrates a detachment apparatus according to some embodiments of the present disclosure.

FIG. 2 illustrates another detachment apparatus according to some embodiments of the present disclosure.

FIG. 3 illustrates an enlarged view of a circuit board component and a portion of a detachment apparatus according to some embodiments of the present disclosure.

### DETAILED DESCRIPTION

In the following detailed description, reference is made to the accompanying drawings, which form a part hereof. In the drawings, similar symbols typically identify similar components, unless context dictates otherwise. The various embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

As more and more electronic products are being consumed and then abandoned, an increasing number of waste circuit boards are produced. To recycle the waste circuit boards, the components on the boards are typically first detached from the boards. After the components are removed, the materials of the circuit board can be recycled by other means, such as by melting. Currently, there are four common methods for disassembling and detaching components from a waste circuit board, including: air heating, infrared heating, laser heating, and liquid heating. However, these methods fail to adequately remove components from the circuit board that are attached using through-hole technology (THT) or surface-mounted technology (SMT). In contrast, the embodiments disclosed herein are able to remove these components and may be used in conjunction with other, known disassembly methods.

In particular, according to some embodiments, a detachment apparatus is configured to detach or remove at least one component from a circuit board. The circuit board may be a waste circuit board whose materials and/or components are going to be recycled. The circuit board may include a number of components and materials. In some cases, to detach components from a circuit board, the soldering is at least partially melted. Once the soldering is removed, the remaining components, which can include THT and SMT components, may be removed or detached from the circuit board. In some embodiments, the components—which are removable using the techniques, systems, or apparatuses disclosed herein—can include any component connected to a circuit board with soldering.

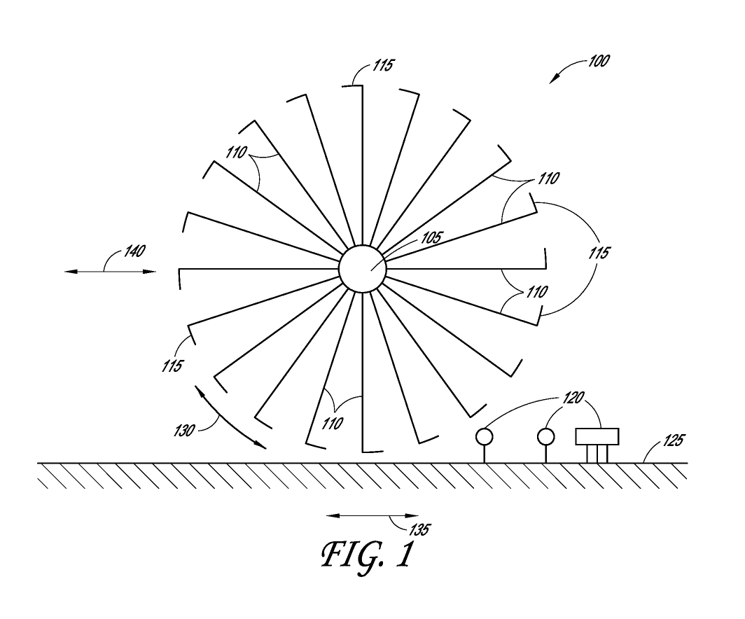

The present disclosure describes, among other things, detachment rollers for disengaging THT and related components from a circuit board. Referring to FIG. 1, detachment roller 100 may include a shaft 105 and levers 110. Shaft 105, which may be referred to as a roller shaft, may be configured to rotate about a central axis. Levers 110 are attached at one end to shaft 105 and positioned radially around shaft 105. Rotation of shaft 105 causes levers 110 to also rotate about the central axis of shaft 105. In some embodiments, the shaft may be rotated at a rate equal to or greater than about 10 rpm. In one embodiment, the rotational speed is at least about 40, 41, 42, 43, 44, 45, 46, 47, 48, 49, 50, 51, 52 53, 54, 55 56, 57, 58, 59, 60, 61, 62, 63, 64, 65, 66, 67, 68, 69, 70, 71, 72, 73, 74, 75, 76, 77, 78, 79 or 80 rpm, or rates between any two of these values (including endpoints). In another embodiment, the rotational speed is not greater than about 500 rpm. In another embodiment, the rotational speed is not more than about 160, 165, 170, 175, 180, 185, 190, 195, 200, 205, 210, 215, 220, 225, 230, 235, 240, 245, 250, 255, 260, 265, 270, 275, 280, 285, 290, 295, 300, 305, 310, 315, 320 or 325 rpm, or rates between any two of these values (including endpoints). In another embodiment, the rotational speed is about 60 rpm to about 300 rpm. Levers 110 include a first end and a second end, the first end being attached to shaft 105. Levers 110 may include at the second end, or their free ends, hook 115 or a comparable mechanism for detaching or removing components 120 from circuit board 125.

Hook 115 may be formed of any suitable shape for removing a component 120 from a circuit board 125. Such shapes include, but are not limited to, a wedge, a prong, a blade, etc. The size of hook 115 may depend on the size and/or type of the component to be removed from the circuit board. Multiple hooks may be the same size or different sizes. Multiple hooks may be the same shape or different shapes. In one embodiment, the hooks range in size from about 1 mm to about 100 cm. In other embodiments, the hook size may be about 5, 10, 15, 20, 25, 30, 35, 40, 45, 50, 55, 60, 65, 70, 75, 80, 85, 90 or 95 mm, or sizes between any two of these values (including endpoints). In still other embodiments, the hook size may be about 2, 3, 4, 5, 6, 7, 8, 9, 10, 11, 12, 13, 14, 15, 16, 17, 18, 19, or 20 mm, or sizes between any two of these values (including endpoints). In another embodiment, the hook size may vary between about 3 mm and about 10 mm. The levers may range from about 10 mm to about 500 mm. In some embodiments, the levers may be about 20, 30, 40, 50, 60, 70, 80, 90, 100, 110, 120, 130, 140, 150, 160, 170, 180, 190, or 200 mm, or ranges between any two of these values (including endpoints). In other embodiments the levers may be at least about 80, 81, 82, 83, 84, 85, 86, 87, 88, 89, 90, 91, 92, 93, 94, 95, 96, 97, 98, 99 or 100 mm. In other embodiments, the levers may be not more than about 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, or 140 mm. In yet another embodiment the lever may vary in length from about 90 mm to about 120 mm. In some embodiments, hooks of more than one size may be used on the same detachment apparatus. In some embodiments, hooks of more than one shape may be used on the same detachment apparatus. In some embodiments, larger components are first removed using larger hooks with smaller components later removed by smaller hooks on either the same or a different detachment apparatus.

Hook 115 may use any number of actions to remove components. In some embodiments, hook 115 engages at least a portion of the component. For example, in some embodiments, hook 115 acts as a knife wedging a sharp edge between the underside of a component and the surface of the circuit board. In some embodiments, hook 115 simply scrapes across the surface of the circuit board thereby removing any components in its path. In some embodiments, hook 115 is configured to pull or apply tension to the component, thereby pulling it from the surface of the circuit board. In some embodiments, hook 115 is configured to pry a component from a circuit board. According to some embodiments, hook 115 is configured to be inserted at least partially between the underside of a component and the surface of a circuit board.

As shown in FIG. 1, components 120 may have any number of shapes and sizes and may use any number of connection technologies including, but not limited to, through-hole technology and surface-mounted technology. In some embodiments, circuit board 125 moves or is caused to be moved by a circuit board support, such as a conveyor belt, in a lateral direction. The conveyor belt may move at a rate equal to or greater than about 1 cm/min. In some embodiments, the conveyor belt has a lateral movement of at least about 10, 15, 20, 25, 30, 35, 40, 45, or 50 cm/min, or ranges between any two of these values (including endpoints). In other embodiments, the conveyor belt has a lateral movement of not greater than about 250, 260, 270, 280, 290, 300, 310, 320, 330, 340 or 350 cm/min, or ranges between any two of these values (including endpoints). In another embodiment, the conveyor belt has a lateral movement of about 30 cm/min to about 300 cm/min. Detachment roller 100 may be configured to rotate in the same direction of movement or in an opposite direction. In some embodiments where detachment roller 100 and circuit board 125 move in the same direction, they may move at relatively different speeds.

For example, referring to FIG. 1, in some embodiments, both detachment roller 100 and circuit board 125 move to the left (that is, in a same direction) and detachment roller 100 rotates at a speed that allows hooks 115 to engage components 120. In other words, components 120 may move faster than hooks 115. In some embodiments, hooks 115 may move faster than components 120, such as where detachment roller 100 and circuit board 125 move to the right in FIG. 1. Thus, hooks 115 could be said to catch the edges of components 120 from behind. Of course in some embodiments, detachment roller 100 and circuit board 125 move in opposite directions. In such cases, hook 115 is able to use the force of the detachment roller as well as the counteracting force of the circuit board to pry or remove components 120 from circuit board 125.

In the embodiment illustrated in FIG. 1, detachment roller 100 can be positioned above circuit board 125. However, in some embodiments, other orientations are possible. For example, in some embodiments, circuit board 125 can be held in a vertical position and detachment roller 100 is positioned next to circuit board 125. In such an arrangement, components 120, after being removed or separated from circuit boar 125 by hooks 115, are able to fall away from circuit board 125 to be collected away from the removal process, thereby not obstructing other components or other hooks. Of course, circuit board 125 could be placed in any position—below, next to, above, or at an angle to—detachment roller 100 so long as the relative movements of circuit board 125 and the normal line or axis of rotation of detachment roller 100 are orthogonal or perpendicular to each other.

Shaft 105 of detachment roller 100 is said to rotate in a rotational direction 130 about a central axis. As mentioned above, the central axis or axis of rotation is generally orthogonal to the relative movement of circuit board 125. Circuit board 125 may be supported by a circuit board support capable of moving circuit board 125 in a lateral direction 135. Rotational direction 130 may be either clockwise or counterclockwise. Lateral direction 135 of circuit board may be to the left or right as shown in FIG. 1 (or up or down as mentioned above). When lateral direction 135 is to the left and rotational direction 130 is clockwise, the directions are said to be the same, or detachment roller 100 and circuit board 125 are said to be moving in the same direction. Similarly, if rotational direction 130 is counterclockwise and lateral direction 135 is to the right, detachment roller 100 and circuit board 125 are said to be moving in the same direction. However, if rotational movement 130 is counterclockwise and lateral direction 135 is to the left, then detachment roller 100 and circuit board 125 are said to be moving in opposite directions.

In some embodiments, movement of circuit board 125 relative to the central axis of shaft 105 is achieved by moving circuit board 125 while the central axis of shaft 105 remains stationary. In some embodiments, both circuit board 125 and the central axis move, but their movements are not the same, thereby creating a relative movement between the two of them. In some embodiments, the central axis of shaft 105 is moved relative to circuit board 125 in a lateral direction 140. In some embodiments, this is achieved by keeping circuit board 125 stationary while detachment roller 100 is moved in a direction parallel to the surface of circuit board 125. In some embodiments, both circuit board 125 and detachment roller 100 move in space in different directions or at different speeds so long as the central axis remains orthogonal to the relative movement of circuit board 125. Thus, it can be said that circuit board 125 may move in lateral direction 135—which may be to the left or to the right—and the central axis of shaft 105 may move in lateral direction 140—which also may be to the left or the right, independent of the direction of lateral direction 135. As mentioned above, other directions—such as vertical or angular movements—are also possible.

According to some embodiments, the movement of circuit board 125 causes the movement of levers 110. For example, in some embodiments, shaft 105 is allowed to rotate freely and is not driven or compelled to move by a motor or other driving mechanism. Circuit board 125 is transported by a circuit board support so that components 120 engage one or more of hooks 115, thereby causing shaft 105 to rotate in the same direction as the movement of circuit board 125. Depending on the nature of hooks 115, a sharp edge may catch on an edge or underside of one of components 120. As circuit board 125 continues to move laterally, component 120 pushes hook 115 in the same direction; however, lever 110 applies a tension force to hook 115 that pulls component 120 up from the surface of circuit board 125.

Referring again to FIG. 1, detachment roller 100 can include a plurality of levers 110, although detachment roller 100 may only include one lever 110. Each lever 110 can have a first end and a second end. The first end of each lever 110 is secured to shaft 105. Levers 110 extend radially outward from shaft 105. In some embodiments, fewer levers 110 are included with detachment roller 100 where detachment roller 100 rotates about the central axis at a higher speed. In some embodiments, slower rotation speeds may translate into more levers 110 being included with detachment roller 100.

In some embodiments, one or more of levers 110 include more than one hook 115. In some embodiments where at least one lever includes more than one hook 115, each hook 115 is either a different size or a different configuration in order to remove a different type of component 120.

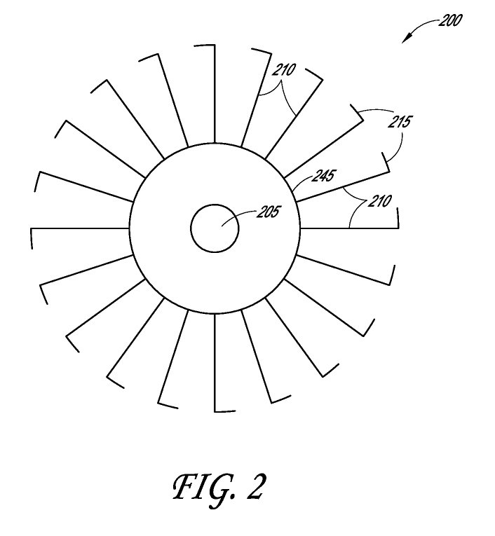

Referring now to FIG. 2, an embodiment of a detachment roller 200 includes a mounting substrate 245 that at least partially surrounds the circumference of shaft 205. In some embodiments mounting substrate 245 is comprised of at least one of a rubber material, a thermoplastic material, a polymer, and combinations thereof. Of course, other materials—such as one or more metals—may also be used alone or in combination with other materials. According to the embodiment illustrated in FIG. 2, levers 210 are secured to detachment roller 200 by way of mounting substrate 245. The first end of levers 210 may be attached to mounting substrate 245.

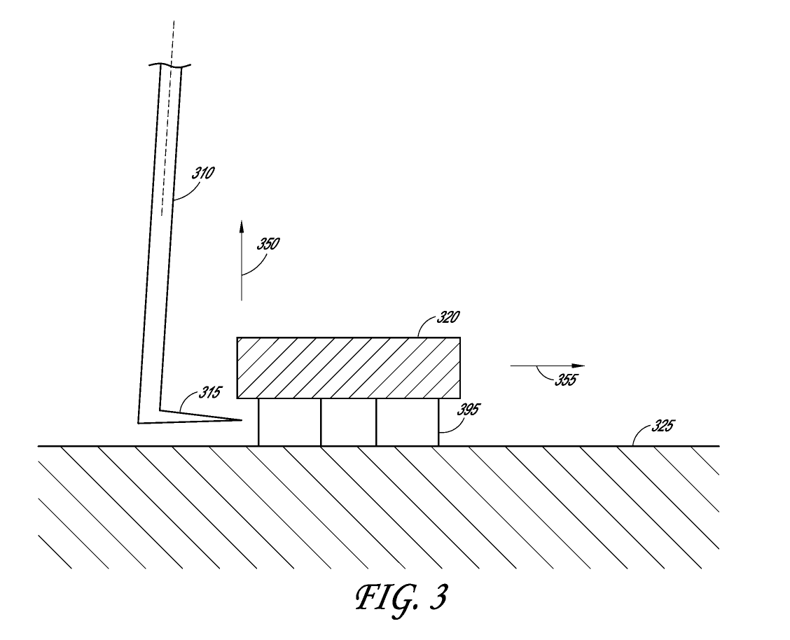

Referring now to FIG. 3, an enlarged view of a lever 310 is illustrated with a hook 315. At the second end of lever 310 is hook 315. Hook 315 includes a first end and a second end, the first end being attached or secured to the second end of lever 310. According to some embodiments, at least a portion of hook 315 (as may be true with hook 215 as well as hook 115) defines a first plane. In some embodiments, at least a portion of lever 310 (as may be true with lever 210 as well as lever 110), defines a second plane. In some embodiments, circuit board 325 defines a third plane, in which the third plane is substantially parallel to the first plane when the second plane is orthogonal to the third plane. In some embodiments, the intersection between the first and second planes defines an acute angle, such that when the first plane is substantially parallel to the third plane, the second plane and third plane also define an acute angle. The angle between the various planes may be selected to maximize the forces (whether upward, lateral, or a combination of upward and lateral) that are applied to component 320 by hook 315 to separate component 320 from circuit board 325.

FIG. 3 also illustrates that component 120 may be attached to circuit board 325 by one or more pins 395. In some embodiments, hook 315 is configured to slip between respective pins 395 to apply a tension force in an upward direction 350 to the underside of component 320. In some embodiments, hook 315 is able to merely catch an exposed edge of component 320, thereby pulling component 320 up at one end. In some embodiments, hook 315 applies a force in a lateral direction 355. In some embodiments, the direction of the force applied by hook 315 to component 320 is a combination of upward direction 350 and lateral direction 355.

According to some embodiments disclosed herein, a method for removing a component from a circuit board can include providing a circuit board having a component attached thereto—such as with soldering—providing a detachment apparatus—such a detachment roller—positioning the detachment apparatus relative to the circuit board, rotating the detachment apparatus so as to cause the hook to come into contact with the component on the circuit board and separating the component from the circuit board. The detachment apparatus can include a shaft configured to rotate about a central axis, and the detachment apparatus can include one or more levers, each having a first end and a second end, the first end being attached to the shaft, and a hook attached at the second end of each lever.

In some embodiments, methods for removing a component from a circuit board can be performed at about room temperature. In some embodiments, removal methods are performed at a temperature below the melting temperature of the material comprising the circuit board. In some embodiments, removal methods are performed at a temperature below the glass transition temperature of the material comprising the circuit board. In some embodiments, the temperature at which the removal process is performed is selected so as to avoid substantial deformation in the circuit board as the detachment apparatus removes components from the circuit board. In some embodiments, the temperature is selected to avoid breaking down any or at least some of the organic substances present in the circuit board.

According to some embodiments, the circuit board is subjected to a heat treatment prior to employing a detachment apparatus. A heat treatment may be used to remove at least some soldering material. Such heat treatment may accomplish the removal of at least some components, though it may also simply soften or weaken the connection of some components to facilitate subsequent removal with the detachment apparatus. In some embodiments, the heat treatment is selected so as to soften at least some of the soldering material while not materially affecting the underlying circuit board. Thus, the temperature of the heat treatment, in some embodiments, is kept below the melting temperature or glass transition temperature (depending on the material and the desired result) of at least some of the materials comprising the circuit board while also being above the melting temperature or glass transition temperature (again, depending on the material and the desired result) of at least some of the soldering material.

In some embodiments, prior to employing a detachment apparatus, larger components or components more securely attached to the circuit board may first be removed. Such components may include surface-mount technology (“SMT”) components or heat sinks that may be bolted to the circuit board.

According to some embodiments, at least some components to be removed by a detachment apparatus are connected to the circuit board by at least one pin or a series of pins. In some embodiments, the component removed with the detachment apparatus may be attached to the circuit board with through-hole technology. In some embodiments, when the hook, the lever, or both apply sufficient force to sever the pin or pins holding the component to the circuit board.

According to some embodiments disclosed herein, a system for removing or detaching a component from a circuit board includes a detachment apparatus (which includes a shaft configured to rotate about a central axis, one or more levers extending radially from the shaft, a hook attached to the end of each lever), a device configured to rotate the shaft, a circuit board support, and a controller. The circuit board support is configured to secure or hold a circuit board having at least one component to be removed. The circuit board is held in place by the circuit board support as the hooks on the end of the one or more levers apply a force to the components to remove the components from the circuit board. The controller is configured to control the rotation device, thereby controlling the rotation of the shaft.

In some embodiments, the circuit board support, in addition to securing the circuit board, moves the circuit board in a direction parallel to a plane of the circuit board, a direction that, in some embodiments, is orthogonal to the direction of the central axis of the shaft. In some embodiments, the circuit board support, and likewise the circuit board, moves in the same direction as the direction of the rotation of the shaft. In some embodiments, the circuit board support moves in a direction opposite to the direction of the rotating shaft. In some embodiments, the rotating lever or levers move at a speed that is different from the speed of the circuit board support.

In some embodiments, the device for rotating the shaft comprises at least one electric motor.

### Examples

Additional embodiments are disclosed in further detail in the following examples, which are not in any way intended to limit the scope of the claims.

### Example 1—Method of Using a Detachment Apparatus

A detachment apparatus is used to remove a component from a circuit board. The detachment apparatus in this example includes a shaft that rotates about a central axis. Attached to the shaft are one or more levers. At the end of each lever is a hook, such that rotation of the shaft causes the levers to also rotate about the central axis. This also causes the hook at the end of each lever to come into contact with one or more components on the circuit board. The detachment apparatus is coupled to a conveyor belt on which a circuit board is moved into contact with the rotating detachment apparatus. The shaft of the detachment apparatus is rotated at 120 rpm and the conveyor belt moves at a rate of 60 cm/min. The levers and hooks contact the circuit board as they move relative to one another. As a hook comes into contact with a component on the circuit board, it engages and pulls the component from the circuit board.

This example shows that a rotating lever/hook effectively removes circuit board components in an automated fashion.

### Example 2—Method of Making a Detachment Apparatus

A detachment apparatus is constructed by providing a rotatable shaft, one or more levers, and a hook for each lever. The levers are attached at one end to the shaft. The levers are attached to the shaft in a hinge-like articulation. On the free end of each lever is a hook. The hook is sized and shaped like a barbed “L” such that it can insert itself between a component and the circuit board to which the component is attached. After attaching the levers with hooks to the shaft, the shaft is coupled to a drive motor that is configured to rotate the shaft at an adjustable rpm in the range of about 60 rpm to about 300 rpm. The detachment apparatus is further configured to operably couple to a conveyor system for transporting and positioning circuit board within a radial distance of about 90 cm to about 120 cm from the levers and hooks, as the boards move with respect to the rotating shaft.

This example shows that a rotating lever/hook can be constructed for the purpose of removing circuit board components in an automated fashion.

### Example 4—System for Detaching a Component from a Circuit Board

A system for detaching a component from a circuit board includes a detachment apparatus, a device and controller for rotating the detachment apparatus, and a circuit board support. The detachment apparatus includes a shaft that rotates about a central axis, one or more levers, each lever having a first end and a second end. The levers are attached to the rotatable shaft at either the first or second end. At the other end is attached a hook designed to separate or remove a component from a circuit board. The circuit board support secures or holds in place the circuit board as the controller activates the device that causes the detachment apparatus to rotate about the axis of the shaft, thereby causing the one or more hooks to come into contact with and remove the components from the circuit board.

The shaft is rotated at a speed of between about 60 rpm and about 300 rpm. The shaft is driven by a motor, such as a variable speed AC motor. The circuit board support is located at a distance of about 90 mm to about 120 mm from the shaft. The length of the levers is approximately the same or slightly less than the distance between the shaft and the circuit board support. The circuit board support includes a conveyor belt, which may itself be driven by a motor. The conveyor belt is driven at a speed of about 30 cm/min to about 300 cm/min.

This example shows that a circuit board component removal system using a rotating shaft with levers can be constructed for the purpose of removing circuit board components in an automated fashion.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (for example, “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into sub-ranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1-13. (canceled)

14. A method for removing at least one component from a circuit board, the method comprising:
providing the circuit board having at least one component attached thereto;
providing a detachment apparatus comprising:
a shaft configured to rotate about a central axis;
at least one lever having a first end and a second end, the at least one lever being attached to the shaft at the first end; and
a hook attached to the second end of the at least one lever;
positioning the detachment apparatus relative to the circuit board;
rotating the detachment apparatus so as to cause the at least one lever to rotate about the central axis of the shaft, thereby causing the hook to come into contact with the at least one component on the circuit board and separate the at least one component from the circuit board; and
severing at least one pin connecting the at least one component to the circuit board by applying sufficient force at the hook.

15. The method of claim 14, wherein the circuit board is a waste circuit board.

16. The method of claim 14, further comprising subjecting the circuit board to a heat treatment to remove at least some solder material from the circuit board prior to rotating the detachment apparatus.

17. The method of claim 14, wherein the at least one component is connected to the circuit board by at least one pin.

18. (canceled)

19. The method of claim 14 further comprising moving the detachment apparatus in a direction substantially parallel to a plane of the circuit board.

20. The method of claim 19, wherein the direction of the movement of the detachment apparatus and the direction of the rotation of the detachment apparatus are the same.

21. The method of claim 19, wherein the direction of the movement of the detachment apparatus and the direction of the rotation of the detachment apparatus are the opposite.

22. The method of claim 14, wherein the hook pries the at least one component from the circuit board to separate the at least one component from the circuit board.

23. The method of claim 14, wherein at least a portion of the hook is inserted between the circuit board and at least a portion of the at least one component.

24. The method of claim 14, wherein the hook engages at least a portion of the at least one component.

25. The method of claim 14, wherein the at least one component comprises a through-hole mounted component.

26. The method of claim 14, wherein the at least one lever comprises a plurality of levers each having a hook, the plurality of levers secured at their first ends to the shaft and extending in a radial direction away from the central axis of the shaft.

27-31. (canceled)

32. The method of claim 14, wherein providing the circuit board having at least one component attached thereto includes positioning the circuit board at a generally vertical orientation.

33. The method of claim 14, wherein severing the at least one pin connecting the at least one component to the circuit board includes severing the at least one component from the circuit board.

34. The method of claim 33, further comprising allowing the at least one severed component to fall down and away from the circuit board.

35. A method for removing at least one component from a circuit board, the method comprising:
providing the circuit board having a plurality of components attached thereto;
providing a detachment apparatus comprising:
a shaft configured to rotate about a central axis;
at least one lever having a first end and a second end, the at least one lever being attached to the shaft at the first end; and
a hook attached to the second end of the at least one lever;
positioning the detachment apparatus relative to the circuit board; and
advancing the circuit board into engagement with the hook, thereby removing at least one component of the plurality of components from the circuit board.

36. The method of claim 35, wherein removing at least one component of the plurality of components from the circuit board comprises severing the at least one pin connecting the at least one component to the circuit board.

37. The method of claim 35, wherein providing the circuit board having at least one component attached thereto comprises positioning the circuit board at a generally vertical orientation.

39. The method of claim 38, further comprising allowing the at least one removed component to fall down and away from the circuit board.

40. The method of claim 39, further comprising collecting the at least one fallen component.

41. A method for removing at least one component from a circuit board, the method comprising:
providing the circuit board having at least one component attached thereto;
providing a detachment apparatus comprising:
a shaft configured to rotate about a central axis;
at least one lever having a first end and a second end, the at least one lever being attached to the shaft at the first end; and
a hook attached to the second end of the at least one lever;
positioning the detachment apparatus relative to the circuit board;
subjecting the circuit board to a heat treatment to remove at least some solder material from the circuit board;
after the heat treatment, rotating the detachment apparatus so as to cause the at least one lever to rotate about the central axis of the shaft, thereby causing the hook to come into contact with the at least one component on the circuit board and separate the at least one component from the circuit board; and
severing the at least one component from the circuit board by applying sufficient force at the hook.
